(19) United States
(12) Patent Application Publication
(10) Pub. No.: US 2011/0005679 A1
(43) Pub. Date: Jan. 13, 2011

(54) PLASMA UNIFORMITY CONTROL THROUGH VHF CATHODE GROUND RETURN WITH FEEDBACK STABILIZATION OF VHF CATHODE IMPEDANCE

(75) Inventors: HIROJI HANAWA, Sunnyvale, CA (US); Kartik Ramaswamy, San Jose, CA (US); Satoru Kobayashi, Mountain View, CA (US)

Correspondence Address: LAW OFFICE OF ROBERT M. WALLACE, 2112 EASTMAN AVENUE, SUITE 102, VENTURA, CA, 93003, US

(73) Assignee: Applied Materials, Inc., Santa Clara, CA (US)

(21) Appl. No.: 12/502,005

(22) Filed: Jul. 13, 2009

(51) Int. Cl. H01L 21/3065; H05K 3/07

(52) U.S. Cl. 156/345.24; 205/641

(57) ABSTRACT

Plasma process uniformity is controlled by maintaining near an optimum value an impedance of a ground return path for VHF source power from an overhead electrode through a workpiece support. A feedback control loop controls a variable reactance element of a reactive circuit that provides isolation between the VHF source power and a lower frequency bias power match circuit.

### BACKGROUND

Plasma enhanced reactive ion etch (PERIE) reactors, for processing workpieces such as semiconductor wafers, employ various techniques for improving uniformity of etch rate across the surface of the workpiece. Typically, radial distribution of etch rate is controlled so as to improve uniformity by controlling gas flow rates in different radial gas injection zones of the reactor, or by controlling magnetic fields in the reactor chamber, for example. In some cases, the RF plasma source power applicator may be divided into radially inner and outer portions, and radial distribution of etch rate further adjusted by controlling the RF power levels applied to the inner and outer zones. Although various combinations of such techniques have enjoyed some success in improving process uniformity, as semiconductor device geometries and critical dimensions continue to be reduced to improve device performance, greater improvements in process uniformity are required. There is a need for further ways of controlling plasma process uniformity.

### SUMMARY

A production workpiece is processed on a workpiece support in a plasma reactor chamber having a ceiling electrode overlying the workpiece support. The reactor includes a source power generator of an RF frequency coupled through an impedance match to the ceiling electrode, and a bias power generator of a bias frequency coupled at a bias impedance match through an RF feed conductor to a workpiece support electrode of the workpiece support. The plasma processing is carried out by providing a ground return path having a controllable RF impedance at the RF frequency through the workpiece support. Prior to processing the production workpiece, a value of the RF impedance is determined that corresponds to a uniform spatial distribution of plasma process rate across a surface of a workpiece processed in the plasma reactor chamber. This may be accomplished by measuring a number of test wafers processed in the chamber at different values of the controllable impedance. The controllable RF impedance is then set to this value. A production workpiece is placed on the workpiece support, and plasma processing is performed by introducing a process gas into the chamber, applying power from the source power generator to the ceiling electrode and applying power from the bias power generator to the workpiece support electrode.

The process further includes sensing at a location along the RF feed conductor an RF parameter at the RF frequency, the RF parameter being either one (or both) of RF current and RF voltage at the RF frequency. The process includes sensing a change in the RF parameter, and responding to the change by modifying the controllable RF impedance of the RF ground return path so as to oppose the change in the RF parameter.

### BRIEF DESCRIPTION OF THE DRAWINGS

So that the manner in which the exemplary embodiments of the present invention are attained and can be understood in detail, a more particular description of the invention, briefly summarized above, may be had by reference to the embodiments thereof which are illustrated in the appended drawings. It is to be appreciated that certain well known processes are not discussed herein in order to not obscure the invention.

FIG. 1 is a schematic diagram of a plasma reactor system in accordance with an embodiment.

FIG. 2A is a block flow diagram of one mode of a process for controlling the system of FIG. 1 which a programmable controller of the system of FIG. 1 carries out.

FIG. 2B is a block flow diagram depicting one implementation of a feedback control feature of the process of FIG. 2A.

FIG. 3 depicts the reactance of a VHF ground return capacitor in the system of FIG. 1 as a function of a mechanical setting.

FIGS. 4A, 4B, 4C and 4D depict radial distribution of etch rate obtained for different values of the reactance of the VHF ground return capacitor.

FIG. 5 is a graph depicting different radial distributions of plasma electron density obtained for different values of the reactances of the VHF ground return capacitor.

FIG. 6 is a graph of a voltage measured at the VHF source power frequency of the reactor system of FIG. 1 as function of different mechanical settings of the ground return capacitor.

FIG. 7 is a graph depicting etch rate radial distribution variance (standard deviation) and etch rate distribution skew measurements obtained at different values of the reactance of the VHF ground return capacitor.

To facilitate understanding, identical reference numerals have been used, where possible, to designate identical elements that are common to the figures. It is contemplated that elements and features of one embodiment may be beneficially incorporated in other embodiments without further recitation. It is to be noted, however, that the appended drawings illustrate only exemplary embodiments of this invention and are therefore not to be considered limiting of its scope, for the invention may admit to other equally effective embodiments.

### DETAILED DESCRIPTION

The present invention concerns a plasma reactor having a capacitively coupled plasma source in the form of a ceiling electrode driven at (or near) a VHF resonance frequency at which the plasma and the electrode resonate together. It is a discovery of the invention that the shape of the plasma ion distribution at the workpiece surface is changed by adjusting the impedance at the VHF resonance frequency through a ground return path through the workpiece support cathode. While not subscribing to any particular theory, it is believed that this is due to the aforementioned resonance setting up electromagnetic wave propagation, enabling the shape of the electromagnetic wave distribution to be affected by the ground return path impedance at the VHF resonance frequency. In accordance with one embodiment, an LC circuit controls a ground return path impedance at the VHF resonance frequency through the cathode. The LC circuit includes a variable reactance (e.g., a variable capacitor) that is set to an optimum value at which the shape of the plasma distribution provides the best uniformity across the workpiece surface. Furthermore, the reactance of that variable reactance is stabilized against fluctuations by a feedback control loop that responds to variations in the voltage or current (or both) through the ground return path at the VHF source power frequency.

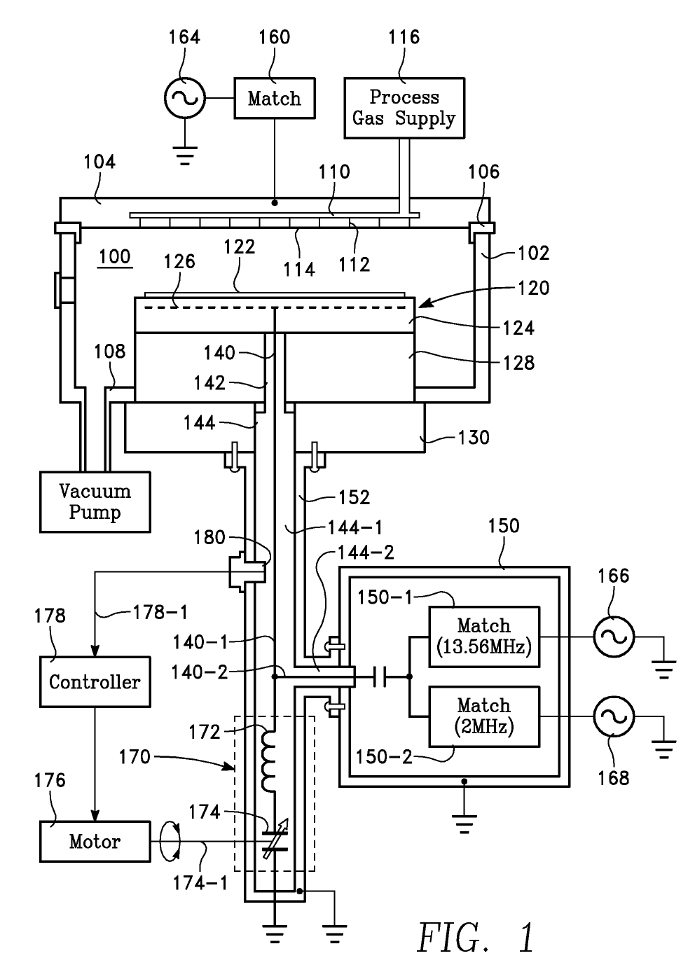

Referring to FIG. 1, a plasma reactor system in accordance with one embodiment includes a reactor chamber 100 defined by a metallic cylindrical side wall 102 supporting a ceiling electrode 104, the wall 102 and electrode 104 being separated by an insulating ring 106. The chamber 100 may further be defined by a floor 108. The ceiling electrode 104 may optionally include an internal gas manifold 110 and plural gas injection ports 112 on its interior surface 114. A process gas supply 116 furnishes process gas to the manifold 110. A cathode or workpiece support pedestal 120 for supporting a workpiece 122 may be an electrostatic chuck (ESC) that includes a ceramic puck 124, an ESC electrode 126 within the puck 124, an aluminum base 128 and an aluminum utilities plate 130. Electrical connection to the ESC electrode 126 is provided by an RF feed conductor 140 extending through the center of the utilities plate 130, the base 128 and the puck 124. The RF feed conductor 140 is insulated from the metal base 128 by a coaxial insulator 142. The RF feed conductor 140 is insulated from the metal plate 130 by a coaxial insulator 144. As indicated in FIG. 1, the RF feed conductor 140 and the coaxial insulator or dielectric 144 extend axially through the bottom of the plate 130, and then in a radial direction toward an bias impedance match box 150. The portion of the coaxial insulator 144 extending below the plate 130 is surrounded by a coaxial metal shield 152. Thus, below the plate 130, the RF feed conductor 140 consists of an axial section 140-1 and a horizontal section 140-2. Likewise, the coaxial insulator 144 consists of an axial section 144-1 and a horizontal section 144-2.

VHF source power at the resonance frequency is applied to the ceiling electrode 104 through a VHF impedance match 160 by a VHF power generator 164. In one embodiment, the resonance frequency is at or near 162 MHz, and the VHF power generator 164 has a frequency of 162 MHz, and a capability of providing tens of kiloWatts of power at that frequency.

HF and MF (or LF) bias power is applied to a terminal end of the RF feed conductor 140-2 through the bias impedance match box 150 by an HF generator 166 (e.g., of a frequency of 13.56 MHz) and an LF generator 168 (e.g., of a frequency of 2 MHz). The bias impedance match box 150 may include an HF impedance match component 150-1 and an LF impedance match component 150-2.

A VHF ground return path for the VHF power from the ceiling electrode 104 is provided through the ESC electrode 126 by coupling the RF feed conductor 140 to ground through an LC circuit 170 having a variable reactance. In one embodiment, the LC circuit 170 consists of an inductor 172 and a variable capacitor 174, and provides a relatively low impedance to 162 MHz current to RF ground. This feature diverts the 162 MHz current away from the bias match box 150, thereby providing isolation for the bias match box 150 from the VHF source power radiated by the ceiling electrode 104. In one embodiment, the LC circuit 170 additionally provides a high impedance at the HF and LF frequencies of the HF and LF bias power generators 166, 168, in order to avoid shorting the bias power generators 166, 168 to ground through the RF feed conductor 140. As one example, the LC circuit 170 may provide a low impedance on the order of 1-30 Ohms at 162 MHz, and provide a very high impedance, on the order of hundreds of thousands of Ohms or megOhms at the HF and LF frequencies of the bias power generators 166, 168. The variable capacitor 174 may be a vacuum capacitor having a nominal capacitance on the order of 20 picoFarads, whose capacitance can be changed by rotation of an electric motor servo 176. While FIG. 1 depicts an embodiment of the LC circuit as a simple series circuit of one inductor 172 and one capacitor 174, other LC circuits may be employed that are more complex and/or have parallel LC elements in them. Moreover, while FIG. 1 depicts the capacitor 174 as being the variable element, the inductor 172 may be a variable reactive element. In more complex embodiments of the LC circuit 170, more than one reactive element may be variable, if desired. The remaining discussion refers to the embodiment of FIG. 1 in which the one variable reactive element of the LC circuit is the vacuum capacitor 174.

A feedback loop controller 178 controls the servo 176. An RF probe 180 that is tuned to sense RF frequencies in a very narrow band centered at the VHF resonance frequency (e.g., 162 MHz), or a resonant frequency in the VHF, HF or MF frequency range, is coupled to the axial section 140-1 of the RF feed conductor 140. If the RF probe 180 is a current probe, it consists of an inductive sensor and is placed close to the surface of the dielectric 144 so that the probe 180 is inductively coupled to the RF current in the coaxial structure of the feed conductor section 140-1 and dielectric 144, with negligible disturbance caused by introduction of the probe 180. If the RF probe 180 is a voltage probe, then the probe 180 is connected to the RF feed conductor section 140-1. Alternatively, the RF probe 180 sense both RF voltage and RF current. The feedback controller 178 has a control input 178-1 that is connected to the output of the RF probe 180. The feedback controller governs the servo motor in response to the output of the RF probe 180. The feedback controller 178 is programmed to compensate for fluctuations in the VHF (resonance frequency) current through (or voltage drop along) the RF feed conductor 140. The exact manner in which the feedback controller 178 is programmed to do this is described below. Initially, the capacitance setting of the vacuum capacitor 174 providing the most uniform process results on a workpiece is empirically determined prior to processing of the production workpiece 122. As discussed below, this entails the processing of a number of test workpieces at different settings of the vacuum capacitor 174. The vacuum capacitor 174 is then placed at the optimum setting before the production workpiece 122 is processed. The feedback loop controller 178 is necessary to stabilize the VHF ground return current (or voltage) to guard against fluctuations that would detract from this optimum condition.

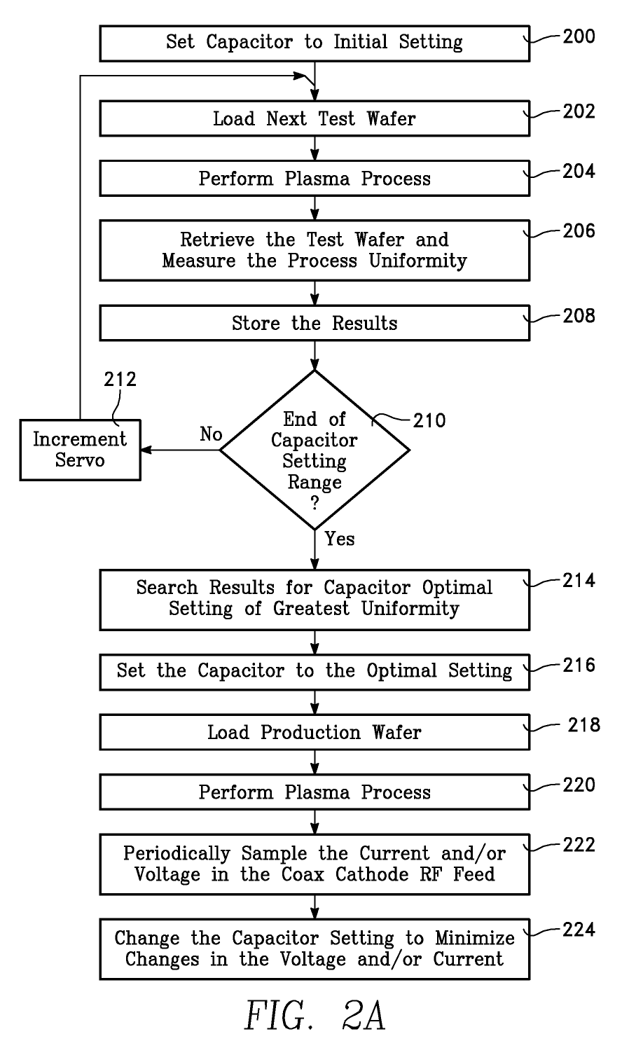

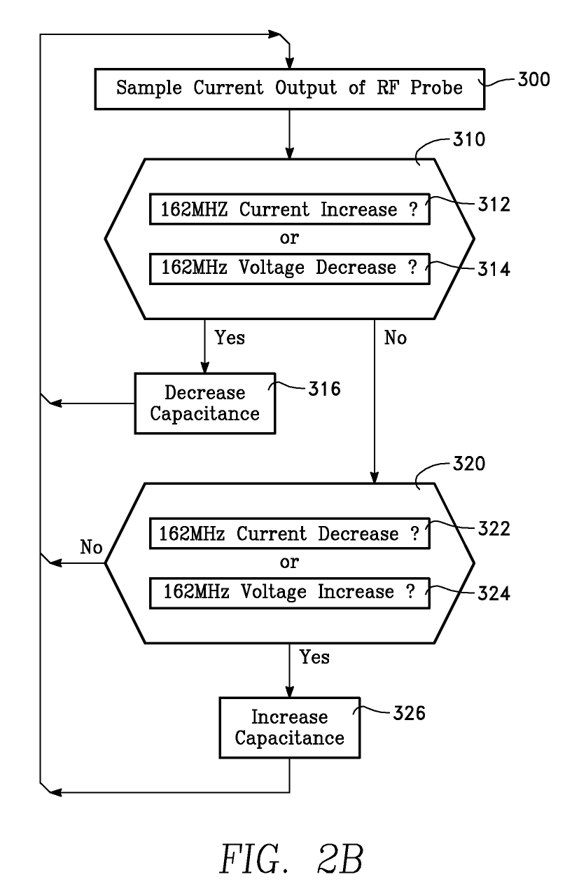

FIG. 2A depicts how embodiments of the present invention can be carried out. First, the optimum setting of the vacuum capacitor 174 is determined. In one embodiment, this is accomplished by setting the vacuum capacitor to an initial value, at which the servo is at a rotational position at the beginning of a predetermined range (block 200 of FIG. 2A). A test wafer is loaded onto the ESC 120 (block 202) and a selected plasma process is performed (block 204), whose parameters (chamber pressure, gas composition, flow rate, source power level, HF and LF bias power levels, etc.) have been predetermined. The test wafer is then removed from the chamber 100 and conventional techniques are employed to determine the spatial distribution of etch rate across the workpiece surface (block 206). This spatial distribution is recorded (block 208) and a determination is made whether the current setting of the vacuum capacitor 174 is at the end of the predetermined range (block 210). If not (NO branch of block 210), the servo axle rotational position is incremented (block 212) by a small predetermined amount, and the next test workpiece is loaded onto the ESC 120 (block 202). The foregoing cycle continues until the end of the servo position range is reached (YES branch of block 210). At this point, the results of the successive etch rate determinations are searched to determine which capacitor setting provided the optimum etch distribution uniformity (e.g., minimum variance or standard deviation) and/or the minimum skew (block 214). The controller 178 sets the capacitor 174 to this optimum setting (block 216), a production workpiece is placed on the ESC 120 (block 218) and the plasma process is performed (block 220). The controller 178 periodically samples the output of the RF probe 180 and determines whether any change occurred since the previous sample (block 222). The controller 178 responds to any such change by changing the setting of the vacuum capacitor 174 (the position of the servo 176) so as to compensate for such a change (block 224).

FIG. 2B depicts one cycle of a feedback control process performed by the controller 178, in accordance with one embodiment. The cycle begins with the controller 178 sampling the current output of the RF probe 180 (block 300 of FIG. 2B). The controller then determines whether the capacitance of the capacitor 174 should be decreased (block 310). In carrying out this determination, the controller 178 may make any one of the following determinations: If the probe 180 is a current probe, the controller 178 determines whether the measured 162 MHz RF current has increased since the previous sample (block 312). If the probe 180 is a voltage probe, the controller 178 determines whether the 162 MHz voltage has decreased since the previous sample (block 314). If either determination is affirmative (YES branch of block 310), then the controller 178 commands the servo 176 to decrease the capacitance of the variable capacitor by a predetermined incremental amount (block 316). Thereafter, the controller returns to the operation of block 300 and repeats the cycle. Otherwise (NO branch of block 310), the controller 178 proceeds to determine whether the capacitance should be increased (block 320). In carrying out this determination, the controller 178 may make any one of the following determinations: If the probe 180 is a current probe, the controller 178 determines whether the measured 162 MHz RF current has decreased since the previous sample (block 322). If the probe 180 is a voltage probe, the controller 178 determines whether the 162 MHz voltage has increased since the previous sample (block 324). If either determination is affirmative (YES branch of block 320), then the controller 178 commands the servo 176 to increase the capacitance of the variable capacitor 174 by a predetermined incremental amount (block 326). Then, the controller 178 returns to the beginning of the cycle at block 300 and repeats the cycle. These steps are effective in reducing changes in the 162 MHz voltage (if the RF probe 180 is a voltage probe) or in reducing changes in the 162 MHz current (if the probe 180 is an RF current probe).

If the variable capacitor 174 is a typical vacuum capacitor, its capacitance is varied by turning a mechanical set screw 174-1 (indicated symbolically in FIG. 1) that is a part of the vacuum capacitor 174, and this task is performed by the servo 176.

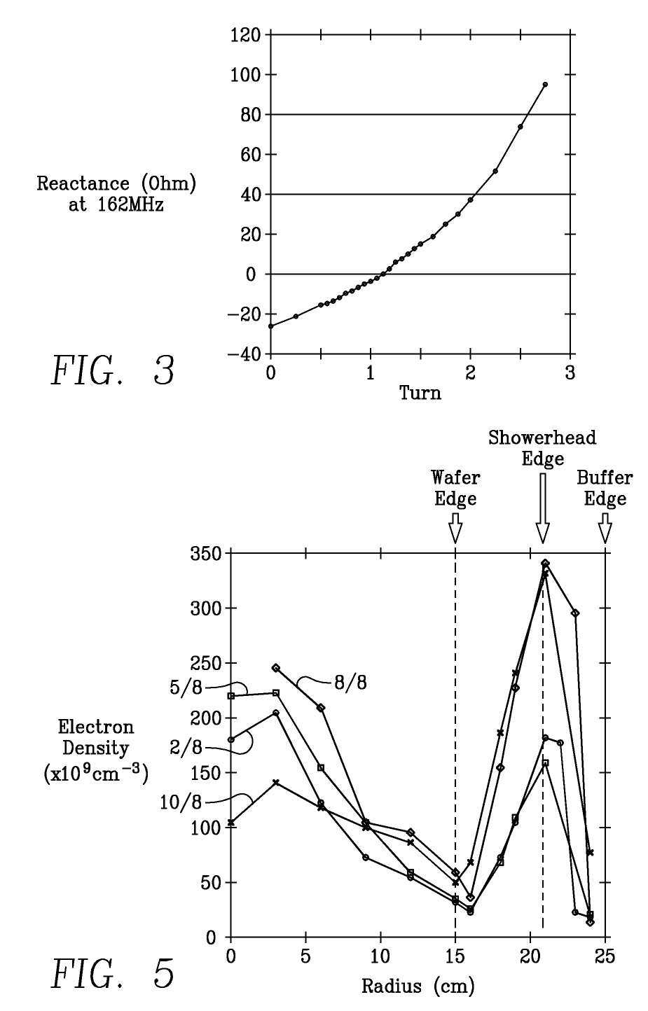

FIG. 3 is a graph depicting the behavior of the impedance of the capacitor 174 at 162 MHz (given in Ohms) as a function of the rotation position, given in turns, of the vacuum capacitor set screw 174-1. The capacitance is varied about a nominal value of 20 picoFarads by turning the set screw 174-1 about 1.5 turns clockwise or counterclockwise.

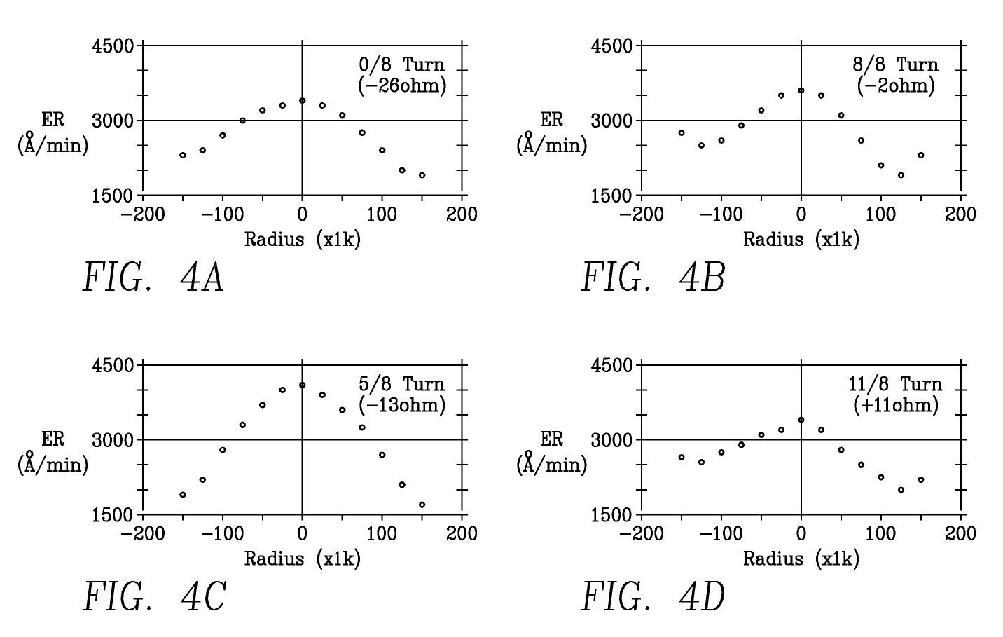

FIGS. 4A through 4D depict the effects of changing the vacuum capacitor settings on the radial distribution of etch rate on different test workpieces (semiconductor wafers). In FIG. 4A, the capacitance setting is at an initial value of zero turns of the set screw 174-1, corresponding to a reactance of −26 Ohms at 162 MHz. FIGS. 4B, 4C and 4D correspond to capacitor settings of −13 Ohms (⅝ turn), −2 Ohms (1 turn) and +11 Ohms (11/8 turn). The +11 Ohm setting of FIG. 4D provides the least variance and least skew in etch rate distribution.

FIG. 5 is a graph of radial distributions of plasma electron density measured for different settings of the variable capacitor 174 (slightly different from the settings of FIGS. 4A-4D in some instances). Each curve is labeled with the corresponding setting, and the different settings are 2/8 turn, ⅝ turn, 8/8 (or 1) turn and 10/8 turn. The least variance among these latter set of choices was obtained at a capacitor setting of 10/8 turn.

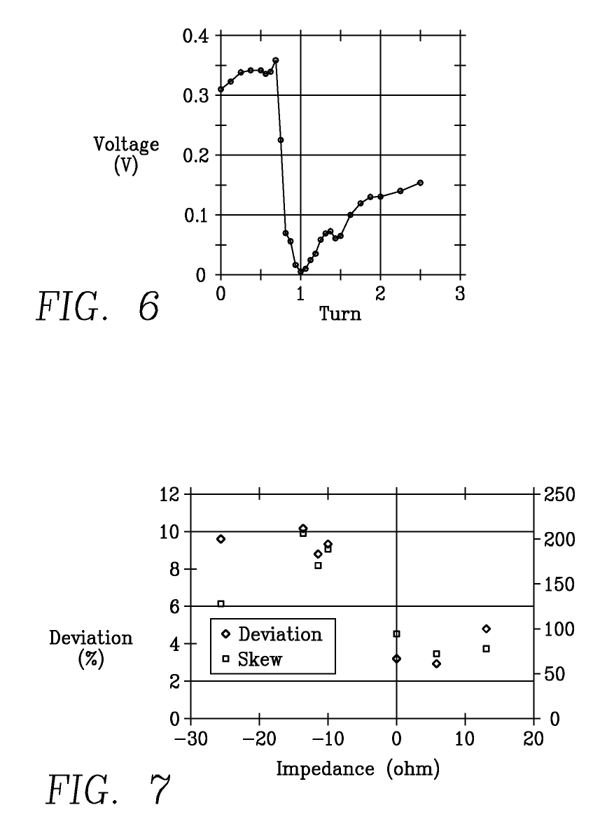

FIG. 6 is a graph of the output of the RF probe 180 as a function of the number of turns of the vacuum capacitor set screw 174-1. FIG. 6 corresponds to an embodiment in which the probe 180 is a voltage probe responsive in a narrow frequency band centered at 162 MHz. The graph of FIG. 6 indicates a dramatic change in 162 MHz voltage at 1.0 turns, which is near the optimal setting of about 1.4 (10/8) turns, where the data discussed above indicates a maximum etch rate distribution uniformity. FIG. 6 therefore shows that the output of the RF probe 180 provides very measurable response to fluctuations in ground return path impedance, providing satisfactory sensitivity for the feedback controller 178. The data of the graph of FIG. 6 extends over a range of zero to 2.5 turns of the motor 176 or vacuum capacitor set screw 174-1. This range may correspond to a range of 162 MHz impedance values from about −30 Ohms to about +15 Ohms. In one embodiment, it is this range within which the steps of blocks 200 through 210 of FIG. 2A are carried out.

FIG. 7 depicts etch rate radial distribution variances obtained from carrying out the repeated measurements of blocks 200 through 210 of FIG. 2A at different reactances at 162 MHz of the vacuum capacitor 174 using successive test wafers. FIG. 7 also depicts skew values obtained from the same test wafers. FIG. 7 indicates that both variance and skew are minimum (optimal) near a reactance of 8 Ohms, corresponding to a set screw position of about 10/8 turn, which is consistent with the data of FIG. 5.

While the foregoing is directed to embodiments of the present invention, other and further embodiments of the invention may be devised without departing from the basic scope thereof, and the scope thereof is determined by the claims that follow.

What is claimed is:

1. A method of processing a production workpiece on a workpiece support in a plasma reactor chamber having a ceiling electrode overlying said workpiece support and a source power generator of an RF frequency coupled through an impedance match to the ceiling electrode, and a bias power generator of a bias frequency coupled at a bias impedance match through an RF feed conductor to a workpiece support electrode of said workpiece support, comprising:
providing a ground return path having a controllable RF impedance at said RF frequency through said workpiece support;
determining a value of said RF impedance corresponding to a uniform spatial distribution of plasma process rate across a surface of a workpiece processed in said plasma reactor chamber;
setting said controllable RF impedance to said value;
placing a production workpiece on said workpiece support, introducing a process gas into the chamber, and applying power from said source power generator to said ceiling electrode and applying power from said bias power generator to said workpiece support electrode;
sensing at a location along said RF feed conductor an RF parameter at said RF frequency, said RF parameter comprising at least one of RF current and RF voltage at said RF frequency;
sensing a change in said RF parameter, and responding to the change by modifying said controllable RF impedance of said RF ground return path so as to oppose the change in said RF parameter.

2. The method of claim 1 wherein said sensing a change comprises periodically sampling said RF parameter and comparing a current sample of said RF parameter with a previous sample of said RF parameter.

3. The method of claim 2 wherein said modifying said controllable RF impedance comprises:
(a) increasing said controllable RF impedance by a predetermined amount if said change in the RF parameter corresponds to an increase in RF current or a decrease in RF voltage;
(b) decreasing said controllable RF impedance by a predetermined amount if said change in the RF parameter corresponds to a decrease in RF current or an increase in RF voltage.

4. The method of claim 1 wherein said controllable RF impedance is on the order of thousands of times greater at said bias power frequency than at said RF frequency of said source power generator.

5. The method of claim 1 wherein said controllable RF impedance is less than 30 Ohms at said RF frequency of said source power generator and is in excess of 100,000 Ohms at said bias frequency of said bias power generator.

6. The method of claim 1 wherein said sensing an RF parameter at said RF frequency comprises sensing said RF parameter in a narrow frequency band that includes said RF frequency and excludes said bias frequency.

7. The method of claim 1 wherein said determining a value of said RF impedance comprises:
successively placing individual ones of a series of test workpieces on said workpiece support, and for each one of said test workpieces:
(a) incrementing said controllable RF impedance by a predetermined amount;
(b) performing a plasma process on the one test workpiece by introducing a process gas into the chamber, and applying power from said source power generator to said ceiling electrode and applying power from said bias power generator to said workpiece support electrode;
(c) measuring uniformity of spatial distribution of process rate across the surface of the one test wafer and recording the result;
after processing of a number of said test wafers and incrementing said controllable RF impedance through a predetermined range, comparing the uniformities measured for said number of test wafers and determining which value of said controllable RF impedance corresponds to a best uniformity.

8. The method of claim 7 wherein said predetermined range of said controllable RF impedance is between about −30 Ohms and +15 Ohms.

9. The method of claim 7 wherein said measuring uniformity of spatial distribution of process rate across the surface of the one test wafer comprises measuring at least one of (a) variance of said spatial distribution, (b) skew of said spatial distribution.

10. The method of claim 1 wherein said RF frequency of said source power generator is a VHF frequency and said bias frequency comprises at least one of an HF frequency and an LF frequency.

11. A method of processing a production workpiece on a workpiece support in a plasma reactor chamber having a ceiling electrode overlying said workpiece support and a source power generator of an RF frequency coupled through an impedance match to the ceiling electrode, and a bias power generator of a bias frequency coupled at a bias impedance match through an RF feed conductor to a workpiece support electrode of said workpiece support, comprising:
providing a ground return path having a controllable RF impedance at said RF frequency through said workpiece support;
determining a value of said RF impedance corresponding to a uniform spatial distribution of plasma process rate across a surface of a workpiece processed in said plasma reactor chamber;
setting said controllable RF impedance to said value;
placing a production workpiece on said workpiece support, introducing a process gas into the chamber, and applying power from said source power generator to said ceiling electrode and applying power from said bias power generator to said workpiece support electrode;
sensing at a location along said RF feed conductor an RF parameter at said RF frequency, said RF parameter comprising at least one of RF current and RF voltage at said RF frequency;
maintaining said RF parameter near a constant value by controlling in a feedback control loop said controllable RF impedance in response to said sensing.

12. The method of claim 11 wherein said maintaining comprises periodically sampling said RF parameter and comparing a current sample of said RF parameter with a previous sample of said RF parameter to determine a change in said RF parameter.

13. The method of claim 12 wherein said controlling in a feedback control loop said controllable RF impedance comprises:
(a) increasing said controllable RF impedance by a predetermined amount if said change in the RF parameter corresponds to an increase in RF current or a decrease in RF voltage;
(b) decreasing said controllable RF impedance by a predetermined amount if said change in the RF parameter corresponds to a decrease in RF current or an increase in RF voltage.

14. The method of claim 11 wherein said controllable RF impedance is on the order of thousands of times greater at said bias power frequency than at said RF frequency of said source power generator.

15. The method of claim 11 wherein said sensing an RF parameter at said RF frequency comprises sensing said RF parameter in a narrow frequency band that includes said RF frequency and excludes said bias frequency.

16. The method of claim 11 wherein said determining a value of said RF impedance comprises:
successively placing individual ones of a series of test workpieces on said workpiece support, and for each one of said test workpieces:
(d) incrementing said controllable RF impedance by a predetermined amount;
(e) performing a plasma process on the one test workpiece by introducing a process gas into the chamber, and applying power from said source power generator to said ceiling electrode and applying power from said bias power generator to said workpiece support electrode;
(f) measuring uniformity of spatial distribution of process rate across the surface of the one test wafer and recording the result;
after processing of a number of said test wafers and incrementing said controllable RF impedance through a predetermined range, comparing the uniformities measured for said number of test wafers and determining which value of said controllable RF impedance corresponds to a best uniformity.

17. A plasma reactor for processing a workpiece, comprising:
a reactor chamber comprising a ceiling electrode and a workpiece support electrode;
a VHF source power generator and a VHF impedance match connected between said VHF source power generator and said ceiling electrode, and a bias power generator of a bias frequency, and a bias impedance match connected to said bias power generator, and an RF feed rod connected between said bias impedance match and said workpiece support electrode;
a variable reactive circuit coupled between ground and a location on said RF feed rod between said bias impedance match and said workpiece support electrode;
RF probe apparatus coupled to said RF feed rod and responsive in a frequency band that includes said VHF frequency and excludes said bias frequency, said RF probe apparatus comprising a probe output representing a measured value of an RF parameter;
a feedback controller having a control input coupled to said probe output, said feedback controller comprising a control output coupled to said variable reactive circuit and adapted to change the reactance said variable reactive circuit to minimize fluctuations in said RF parameter.

18. The reactor of claim 17 wherein said reactive circuit has a lower impedance at said VHF frequency than at said bias frequency.

19. The reactor of claim 17 wherein said reactive circuit comprises an inductor and a variable capacitor and a servo capable of changing a capacitance of said variable capacitor, said control output of said feedback controller being connected to said servo.

20. The reactor of claim 19 wherein said RF feed rod comprises an axial section extending from said workpiece support electrode toward said bias impedance match, and a radial section extending from an end of said axial section to said bias impedance match, and wherein said RF probe apparatus is coupled to a portion of said axial section and said reactive circuit is connected between said axial section and ground.
